(19) United States
(12) Patent Application Publication
(10) Pub. No.: US 2020/0312574 A1
(43) Pub. Date: Oct. 1, 2020

(54) PHOTOELECTRIC CONVERSION ELEMENT AND MANUFACTURING METHOD THEREOF

(71) Applicant: SHARP KABUSHIKI KAISHA, Sakai City (JP)

(72) Inventors: HIROSHI SUGIMURA, Sakai City (JP); SHINTARO MIYANISHI, Sakai City (JP); TAKAHIRO KURAUCHI, Sakai City (JP)

(21) Appl. No.: 16/812,251

(22) Filed: Mar. 6, 2020

(30) Foreign Application Priority Data
Mar. 29, 2019 (JP) 2019-068466

(51) Int. Cl. H01G 9/20; H01G 9/00; H01L 51/42

(52) U.S. Cl. CPC H01G 9/2009; H01L 51/4266; H01G 9/0036

(57) ABSTRACT

A photoelectric conversion element includes an electron transport layer, a hole transport layer, and a light absorption layer disposed between the electron transport layer and the hole transport layer. The light absorption layer includes a perovskite compound having a needle-like crystal structure, and a binder resin. The binder resin preferably contains a polyvinyl butyral resin or a cellulose resin.

### BACKGROUND OF THE INVENTION

### Field of the Invention

The present invention relates to a photoelectric conversion element and a manufacturing method thereof.

### Description of the Background Art

Photoelectric conversion elements are used, for example, in optical sensors, copiers, solar cells, and the like. Among these, solar cells are becoming genuinely widespread as a representative method of utilizing of renewable energy. Solar cells that use an inorganic photoelectric conversion element (such as silicon-based solar cells, copper indium gallium selenide (CIGS)-based solar cells, and cadmium telluride (CdTe)-based solar cells) are being widely used.

On the other hand, solar cells that use an organic photoelectric conversion element (such as organic thin-film solar cells and dye-sensitized solar cells) are being studied. Since solar cells that use such an organic photoelectric conversion element can be produced by a coating treatment without the use of a vacuum process, manufacturing costs can potentially be significantly reduced. Therefore, there is an expectation that solar cells that use an organic photoelectric conversion element will represent the next generation of solar cells.

In the area of organic photoelectric conversion elements, photoelectric conversion elements that use a compound having a perovskite crystal structure (hereinafter, sometimes referred to as a perovskite compound) in a light absorption layer have been studied in recent years. Examples of the perovskite compound include lead complexes. Photoelectric conversion elements that use a perovskite compound in the light absorption layer have excellent photoelectric conversion efficiency. Furthermore, Japanese Unexamined Patent Application Publication No. 2014-72327 describes that in photoelectric conversion elements using a perovskite compound, the use of carbon nanotubes as a hole transport material further improves the photoelectric conversion efficiency.

### SUMMARY OF THE INVENTION

However, photoelectric conversion elements that use a perovskite compound in the light absorption layer are readily affected by moisture (humidity) during the manufacturing stage. Specifically, when photoelectric conversion elements that use a perovskite compound are formed in air (specifically, in air having a humidity of 50% RH or more), the perovskite compound forms a needle-like crystal structure due to the influence of moisture, which results in a porous light absorption layer. When a charge transport layer is formed on such a porous light absorption layer by a coating treatment, the charge transport material permeates into the light absorption layer, and a short circuit causes a decrease in photoelectric conversion efficiency. In particular, as described in Japanese Unexamined Patent Application Publication No. 2014-72327, when using a charge transport material (hole transport material) having excellent conductivity such as carbon nanotubes, the short circuit described above causes a significant decrease in photoelectric conversion efficiency.

Therefore, photoelectric conversion elements that use a perovskite compound are generally produced in an environment with the lowest possible humidity (for example, inside a glove box). In such an environment, the perovskite compound forms a plate-like crystal structure. Therefore, it is possible to suppress a decrease in photoelectric conversion efficiency due to the short circuit described above. However, when a photoelectric conversion element that uses a perovskite compound is produced in such an environment, manufacturing costs tend to increase.

Furthermore, a light absorption layer containing a perovskite compound having a plate-like crystal structure tends to have low flexibility. Therefore, it is difficult for photoelectric conversion elements that use a perovskite compound having a plate-like crystal structure in the light absorption layer to be provided with flexibility. In addition, the impact resistance tends to be low.

The present invention has been made in view of the above problems. An object of the present invention is to provide a photoelectric conversion element having excellent photoelectric conversion efficiency, low manufacturing costs, a light absorption layer which has flexibility, and a manufacturing method thereof.

A photoelectric conversion element according to an embodiment of the present invention includes an electron transport layer, a hole transport layer, and a light absorption layer disposed between the electron transport layer and the hole transport layer. The light absorption layer includes a perovskite compound having a needle-like crystal structure, and a binder resin.

A manufacturing method of a photoelectric conversion element according to another embodiment of the present invention includes forming a first charge transport layer containing a first charge transport material, forming a light absorption layer on the first charge transport layer, and forming a second charge transport layer on the light absorption layer by coating a second charge transport layer coating solution containing a second charge transport material. One of the first charge transport material and the second charge transport material is an electron transport material, and the other is a hole transport material. The light absorption layer includes a perovskite compound having a needle-like crystal structure, and a binder resin.

According to the photoelectric conversion element of the present invention, and the manufacturing method thereof, it is possible to provide a photoelectric conversion element having excellent photoelectric conversion efficiency, low manufacturing cost, and a light absorption layer which has flexibility.

### BRIEF DESCRIPTION OF THE DRAWINGS

FIG. 1 is a diagram showing an example of a photoelectric conversion element according to an embodiment of the present invention.

FIG. 2 is a diagram showing a basic unit cell of a perovskite crystal structure.

FIG. 3 is a photograph showing a porous perovskite compound layer formed in Example 1 of the present invention.

FIG. 4 is a photograph showing a light absorption layer formed in Example 1 of the present invention.

FIG. 5 is a photograph showing a light absorption layer formed in Example 6 of the present invention.

### DESCRIPTION OF THE PREFERRED EMBODIMENTS

Hereinafter, embodiments of the present invention will be described with reference to the drawings. However, the present invention is in no way limited to the embodiments. The present invention may be implemented with appropriate modifications within the scope of the present invention. In the drawings, identical or equivalent parts are denoted by the same reference symbols, and the description may be omitted. Furthermore, acryl and methacryl may be collectively referred to as “(meth)acryl”. In addition, acrylate and methacrylate may be collectively referred to as “(meth)acrylate”. Each material described in the embodiments of the present invention may be used alone or in combination of two or more, unless otherwise specified.

### First Embodiment: Photoelectric Conversion Element

A first embodiment of the present invention relates to a photoelectric conversion element. The photoelectric conversion element according to the present embodiment includes an electron transport layer, a hole transport layer, and a light absorption layer disposed between the electron transport layer and the hole transport layer. The light absorption layer includes a perovskite compound having a needle-like crystal structure, and a binder resin.

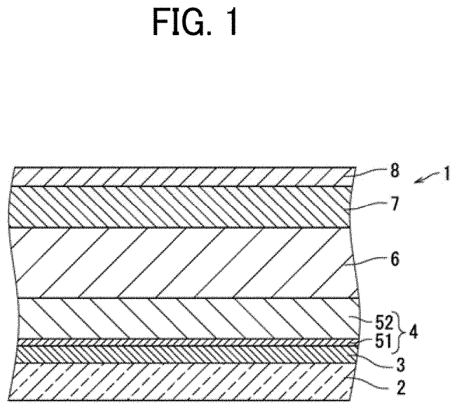

First, an example of the photoelectric conversion element according to the present embodiment will be described with reference to FIG. 1. The photoelectric conversion element shown in FIG. 1 includes, in order from one surface, a base 2, a first conductive layer 3, an electron transport layer 4, a light absorption layer 6, a hole transport layer 7, and a second conductive layer 8. The electron transport layer 4 has a two-layer structure including a dense titanium oxide layer 51 on the first conductive layer 3 side, and a porous titanium oxide layer 52 on the light absorption layer 6 side. The light absorption layer 6 includes a perovskite compound having a needle-like crystal structure, and a binder resin. When in use, for example, the photoelectric conversion element 1 irradiates light (such as sunlight) with respect to a surface on the base 2 side. However, when in use, the photoelectric conversion element 1 may irradiate light with respect to a surface on the second conductive layer 8 side.

The photoelectric conversion element 1 according to the present embodiment has the following advantages. The light absorption layer 6 included in the photoelectric conversion element 1 has flexibility because it is not a layer in which the perovskite compound is densely packed. Therefore, the photoelectric conversion element 1 has excellent impact resistance. Furthermore, the light absorption layer 6 contains a perovskite compound having a needle-like structure and a binder resin. The voids in a porous region formed by the perovskite compound is filled with the binder resin. Therefore, even when the photoelectric conversion element 1 is produced in air, it is possible to suppress the permeation of the charge transport material into the light absorption layer 6 when the charge transport layers (electron transport layer 4 or hole transport layer 7) are formed. As a result, the photoelectric conversion element 1 suppresses the short circuit of the light absorption layer 6, and is capable of sufficiently exhibiting excellent photoelectric conversion efficiency, which arises due to the perovskite compound. As described above, the photoelectric conversion element 1 is produced at low cost in air.

### Base

Examples of the shape of the base 2 include a flat plate shape, a film shape, and a cylindrical shape. If light is to be irradiated with respect to the surface on the base 2 side of the photoelectric conversion element 1, the base 2 is transparent. In this case, examples of the material of the base 2 include transparent glass (more specifically, soda lime glass, non-alkali glass, and the like), and a transparent resin having heat resistance. If light is to be irradiated with respect to the surface on the second conductive layer 8 side of the photoelectric conversion element 1, the base 2 may be opaque. In this case, examples of the material of the base 2 include aluminum, nickel, chromium, magnesium, iron, tin, titanium, gold, silver, copper, tungsten, alloys of these metals (such as stainless steel), and ceramics.

### First Conductive Layer

The first conductive layer 3 corresponds to a cathode of the photoelectric conversion element 1. Examples of the material constituting the first conductive layer 3 include a transparent conductive material and a non-transparent conductive material. Examples of the transparent conductive material include copper iodide (CuI), indium tin oxide (ITO), tin oxide (SnO₂), fluorine-doped tin oxide (FTO), aluminum-doped zinc oxide (AZO), indium zinc oxide (IZO), and gallium-doped zinc oxide (GZO). Examples of the non-transparent conductive material include sodium, sodium-potassium alloys, lithium, magnesium, aluminum, magnesium-silver mixtures, magnesium-indium mixtures, aluminum-lithium alloys, aluminum-aluminum oxide mixtures (Al/Al₂O₃), and aluminum-lithium fluoride mixtures (Al/LiF).

The thickness of the first conductive layer 3 is not particularly limited, and may be any thickness that enables the desired characteristics to be obtained (such as an electron transporting property and transparency).

### Electron Transport Layer

The electron transport layer 4 is a layer that transports electrons generated by photoexcitation in the light absorption layer 6 to the first conductive layer 3. For this reason, the electron transport layer 4 preferably contains a material that easily causes the electrons generated in the light absorption layer 6 to migrate to the first conductive layer 3. In the photoelectric conversion element 1, the electron transport layer 4 includes titanium oxide. Specifically, the electron transport layer 4 includes a dense titanium oxide layer 51 having a relatively small porosity, and a porous titanium oxide layer 52 which is a porous layer having a higher porosity than the dense titanium oxide layer 51. The content ratio of titanium oxide in the electron transport layer 4 is, for example, 95 mass % or more, and preferably 100 mass %. Hereinafter, the dense titanium oxide layer 51 and the porous titanium oxide layer 52 will be described.

### Dense Titanium Oxide Layer

The dense titanium oxide layer 51 has a low porosity. Therefore, when the photoelectric conversion element 1 is produced, the light absorption material (perovskite compound) used for forming the light absorption layer 6 hardly permeates into the layer. For this reason, when the photoelectric conversion element 1 includes the dense titanium oxide layer 51, contact between the light absorption material and the first conductive layer 3 is suppressed. Furthermore, when the photoelectric conversion element 1 includes the dense titanium oxide layer 51, contact between the first conductive layer 3 and the second conductive layer 8, which causes a reduction in electromotive force, is suppressed. The thickness of the dense titanium oxide layer 51 is preferably 5 nm or more and 200 nm or less, and more preferably 10 nm or more and 100 nm or less.

### Porous Titanium Oxide Layer

The porous titanium oxide layer 52 has a high porosity. Therefore, when the photoelectric conversion element 1 is produced, the light absorption material used for forming the light absorption layer 6 easily permeates into the pores of the layer. For this reason, when the photoelectric conversion element 1 includes the porous titanium oxide layer 52, the contact area between the light absorption layer 6 and the electron transport layer 4 is maximized. Consequently, the electrons generated by photoexcitation in the light absorption layer 6 efficiently migrate to the electron transport layer 4. The thickness of the porous titanium oxide layer 52 is preferably 100 nm or more and 2,000 nm or less, and more preferably 200 nm or more and 1,500 nm or less.

### Light Absorption Layer

The light absorption layer 6 is a layer that contains a light absorption material (a perovskite compound having a needle-like crystal structure) and a binder resin. It absorbs the light that enters the photoelectric conversion element 1 to generate electrons and holes. Specifically, when light enters the light absorption layer 6, the low-energy electrons contained in the light absorption material are photoexcited to generate high-energy electrons and holes. The generated electrons migrate to the electron transport layer 4. The generated holes migrate to the hole transport layer 7. Charge separation occurs when the electrons and holes migrate as described above.

In the light absorption layer 6, for example, porous regions are formed due to the perovskite compound having a needle-like crystal structure, and the voids in the porous regions are filled with a binder resin.

### Perovskite Compound

The long axis length of the perovskite compound is preferably 5 μm or more and 50 μm or less, and more preferably 7 μm or more and 20 μm or less. The ratio of the long axis length of the perovskite compound with respect to the short axis length (aspect ratio) is preferably 5 or more and 30 or less, and more preferably 10 or more and 20 or less. As a result of setting the long axis length and the aspect ratio of the perovskite compound in the above ranges, the voids in the porous region formed from the perovskite compound are more easily filled with the binder resin. The long axis length and the aspect ratio of the perovskite compound are measured using the same methods as those described in the examples.

From the perspective of improving photoelectric conversion efficiency, the perovskite compound is preferably a compound represented by the following general formula (1) (hereinafter, sometimes referred to as the perovskite compound (1)).

ABX₃ (1)

In the general formula (1), A represents an organic molecule, B represents a metal atom, and X represents a halogen atom. In the general formula (1), the three X atoms may be the same or different from each other.

The perovskite compound (1) is an organic-inorganic hybrid compound. An organic-inorganic hybrid compound is a compound composed of an inorganic material and an organic material. The photoelectric conversion element 1 using the perovskite compound (1), which is an organic-inorganic hybrid compound, is also referred to an organic-inorganic hybrid photoelectric conversion element.

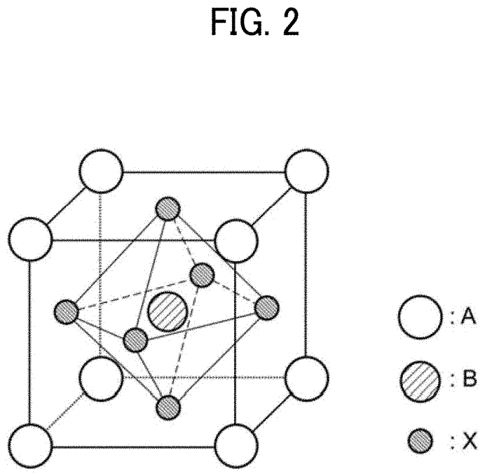

FIG. 2 is a schematic diagram showing a cubic basic unit cell of the crystal structure of the perovskite compound (1). The basic unit cell includes organic molecules A disposed at each vertex, a metal atom B disposed at the body center, and halogen atoms X disposed at each face center.

The fact that the light absorption material has a cubic basic unit cell is confirmed by using an X-ray diffraction method. Specifically, a light absorption layer 6 containing a light absorption material is formed on a glass plate. Then, the light absorption layer 6 is collected in powder form, and a diffraction pattern of the collected light absorption layer 6 (light absorption material) in powder form is measured using a powder X-ray diffractometer. Alternatively, the light absorption layer 6 is collected in powder form from the photoelectric conversion element 1, and a diffraction pattern of the collected light absorption layer 6 (light absorption material) in powder form is measured using a powder X-ray diffractometer.

In the general formula (1), examples of the organic molecule represented by A include alkylamine compounds, alkylammonium compounds, and nitrogen-containing heterocyclic compounds. In the perovskite compound (1), the organic molecule represented by A may be only one type of organic molecule, or two or more types of organic molecules.

Examples of the alkylamine compound include methylamine, ethylamine, propylamine, butylamine, pentylamine, hexylamine, dimethylamine, diethylamine, dipropylamine, dibutylamine, dipentylamine, dihexylamine, trimethylamine, triethylamine, tripropylamine, tributylamine, tripentylamine, trihexylamine, ethylmethylamine, methylpropylamine, butylmethylamine, methylpentylamine, hexylmethylamine, ethylpropylamine, and ethylbutylamine.

An alkylammonium compound is an ionized product of the alkylamines mentioned above. Examples of the alkylammonium compound include methylammonium (CH₃NH₃), ethylammonium, propylammonium, butylammonium, pentylammonium, hexylammonium, dimethylammonium, diethylammonium, dipropylammonium, dibutylammonium, dipentylammonium, dihexylammonium, trimethylammonium, triethylammonium, tripropylammonium, tributylammonium, tripentylammonium, trihexylammonium, ethylmethylammonium, methylpropylammonium, butylmethylammonium, methylpentylammonium, hexylmethylammonium, ethylpropylammonium, and ethylbutylammonium.

Examples of the nitrogen-containing heterocyclic compound include imidazole, azole, pyrrole, aziridine, azirine, azetidine, azeto, azole, imidazoline, and carbazole. The nitrogen-containing heterocycic compound may be an ionized product. Phenethylammonium is preferred when the nitrogen-containing heterocyclic compound is an ionized product.

The organic molecule represented by A is preferably methylamine, ethylamine, propylamine, butylamine, pentylamine, hexylamine, methylammonium, ethylammonium, propylammonium, butylammonium, pentylammonium, hexylammonium or phenethylammonium, more preferably methylamine, ethylamine, propylamine, methylammonium, ethylammonium or propylammonium, and even more preferably methylammonium.

In the general formula (1), examples of the metal atom represented by B include lead, tin, zinc, titanium, antimony, bismuth, nickel, iron, cobalt, silver, copper, gallium, germanium, magnesium, calcium, indium, aluminum, manganese, chromium, molybdenum, and europium. In the perovskite compound (1), the metal atom represented by B may be only one type of metal atom, or two or more types of metal atoms. From the perspective of improving the light absorption characteristics and the charge generation characteristics of the light absorption layer 6, the metal atom represented by B is preferably a lead atom.

In the general formula (1), examples of the halogen atom represented by X include a fluorine atom, a chlorine atom, a bromine atom, and an iodine atom. In the perovskite compound (1), the halogen atom represented by X may be one type of halogen atom, or two or more types of halogen atoms. From the perspective of narrowing the energy band gap of the perovskite compound (1), the halogen atom represented by X is preferably an iodine atom. Specifically, among the three X atoms, it is preferable for at least one of the X atoms to represent an iodine atom, and more preferable for the three X atoms to represent iodine atoms.

The perovskite compound (1) is preferably a compound represented by the general formula “CH₃NH₃PbX₃ (where X represents a halogen atom)”, and is more preferably CH₃NH₃PbI₃. By using a compound represented by the general formula “CH₃NH₃PbX₃” (specifically CH₃NH₃PbI₃) as the perovskite compound (1), electrons and holes are generated more efficiently in the light absorption layer 6. As a result, the photoelectric conversion efficiency of the photoelectric conversion element 1 is further improved.

### Binder Resin

The binder resin is preferably a polyvinyl butyral resin or a cellulose resin (specifically an ethyl cellulose resin). When forming the light absorption layer 6, it is usually necessary to dissolve the binder resin in a solvent. At that time, the viscosity of the solution containing the binder resin is preferably relatively low. Furthermore, the solvent for dissolving the binder resin is preferably a solvent that hardly affects the crystal structure of the perovskite compound (such as toluene or chlorobenzene). From the perspective described above, the binder resin is preferably soluble in a solvent that hardly affects the crystal structure of the perovskite compound, and has a relatively low viscosity when dissolved in such a solvent. Polyvinyl butyral resins and cellulose resins are preferable as the binder resin because they satisfy the above conditions.

From the perspective of improving the photoelectric conversion efficiency of the photoelectric conversion element 1 and the flexibility of the light absorption layer 6, the content ratio of the binder resin in the light absorption layer 6 is preferably 0.1 mass % or more and 2.0 mass % or less.

The light absorption layer 6 may be a layer composed only of the perovskite compound having a needle-like crystal structure and the binder resin. Furthermore, the light absorption layer 6 may further include another component (such as a light absorption material other than the perovskite compound) in addition to the perovskite compound and the binder resin. The total content ratio of the perovskite compound and the binder resin in the light absorption layer 6 is preferably 80 mass % or more, and is more preferably 100 mass %.

### Hole Transport Layer

The hole transport layer 7 is a layer that captures the holes generated in the light absorption layer 6, and transports the holes to the second conductive layer 8 serving as the anode. For example, the hole transport layer 7 is mainly composed of a hole transport material.

Examples of the hole transport material include organic hole transport materials and inorganic hole transport materials. Examples of the organic hole transport material include Spiro-MeOTAD(2,2′,7,7′-tetrakis [N,N-di-P-methoxyphenylamino]-9,9′-spirobifluorene), pyrazoline compounds, arylamine compounds, stilbene compounds, enamine compounds, polypyrrole compounds, polyvinylcarbazole compounds, polysilane compounds, butadiene compounds, polysiloxane compounds having an aromatic amine on a side chain or on the main chain, polyaniline compounds, polyphenylenevinylene compounds, polythienylenevinylene compounds, and polythiophene compounds. Examples of the inorganic hole transport material include carbon nanotubes and copper thiocyanate (CuSCN). Examples of carbon nanotubes include multi-walled carbon nanotubes (MWCNT) and single-walled carbon nanotubes (SWCNT). The hole transport material is preferably composed of carbon nanotubes, and more preferably multi-walled carbon nanotubes.

If necessary, the hole transport layer 7 may further contain an organic binder resin, a plasticizer, and the like. On the other hand, the hole transport layer 7 may contain only the hole transport material. The content ratio of the hole transport material in the hole transport layer 7 is preferably 30 mass % or more and 100 mass % or less, and more preferably 50 mass % or more and 100 mass % or less.

The thickness of the hole transport layer 7 is preferably 20 nm or more and 2,000 nm or less, and more preferably 200 nm or more and 600 nm or less. As a result of setting the thickness of the hole transport layer 7 to be 20 nm or more and 2,000 nm or less, the holes generated in the light absorption layer 6 can smoothly and efficiently migrate to the second conductive layer 8.

If light is to be irradiated with respect to the surface on the second conductive layer 8 side of the photoelectric conversion element 1, from the perspective of ensuring transparency, the hole transport layer 7 is preferably an amorphous layer.

### Second Conductive Layer

The second conductive layer 8 corresponds to an anode of the photoelectric conversion element 1. Examples of the material constituting the second conductive layer 8 include metals, transparent conductive inorganic materials, conductive fine particles, and conductive polymers (specifically transparent conductive polymers). Examples of metals include gold, silver, and platinum. Examples of transparent inorganic conductive materials include copper iodide (CuI), indium tin oxide (ITO), tin oxide (SnO₂), fluorine-doped tin oxide (FTO), aluminum-doped zinc oxide (AZO), indium zinc oxide (IZO), and gallium-doped zinc oxide (GZO). Examples of conductive fine particles include silver nanowires and carbon nanofibers. Examples of transparent conductive polymers include polymers containing poly(3,4-ethylenedioxythiophene) and polystyrenesulfonic acid (PEDOT/PSS).

If light enters from the second conductive layer 8 side of the photoelectric conversion element 1, in order to enable the light to reach the light absorption layer 6, the second conductive layer 8 is preferably transparent or semi-transparent, and more preferably transparent. The material constituting a transparent or semi-transparent second conductive layer 8 is preferably a transparent conductive inorganic material or a transparent conductive polymer. The thickness of the second conductive layer 8 is preferably 50 nm or more and 1,000 nm or less, and more preferably 100 nm or more and 300 nm or less.

### Other

The photoelectric conversion element 1, which represents an example of the photoelectric conversion element according to the present embodiment, has been described above with reference to FIG. 1. However, the photoelectric conversion element according to the present embodiment is not limited to the photoelectric conversion element 1. For example, the following aspects can be changed.

The photoelectric conversion element according to the present embodiment may further include a surface layer on the second conductive layer. The surface layer is a layer that inhibits the deterioration of the interior of the photoelectric conversion element by atmospheric moisture and oxygen. Furthermore, the surface layer is a layer that protects the outer surface from impacts and scratches when the photoelectric conversion element is being used. The material constituting the surface layer is preferably a material having a high gas barrier property. The surface layer is formed using, for example, a resin composition, a shrink film, a wrap film, a clear paint, or the like. On the other hand, it is preferable for the surface layer to not be included if the photoelectric conversion element is used by being housed in a sealed container.

If light enters from the surface layer side of the photoelectric conversion element, the surface layer is preferably transparent or semi-transparent, and more preferably transparent.

The electron transport layer does not have to contain titanium oxide. For example, the electron transport layer may include a dense layer constituted by a material other than titanium oxide, and a porous layer constituted by a material other than titanium oxide. Furthermore, the electron transport layer may be a single layer or a multilayer structure having three or more layers.

The photoelectric conversion element according to the embodiment does not have to include the base, the first conductive layer, and the second conductive layer. That is to say, in the photoelectric conversion element, the base, the first conductive layer, and the second conductive layer may each be omitted. Furthermore, if the photoelectric conversion element according to the present embodiment includes a base, the base may be conductive. In this case, the base also functions as the first conductive layer.

Among the layers included in the photoelectric conversion element according to the present embodiment, the layers other than the light absorption layer (that is to say, the hole transport layer and the electron transport layer, and the optional configurations which include the base, the first conductive layer, the second conductive layer, and the surface layer) preferably have flexibility. As described above, the light absorption layer has flexibility. As a result, because the layers other than the light absorption layer have flexibility, it is possible for the photoelectric conversion element to be provided with flexibility.

### Second Embodiment: Manufacturing Method of Photoelectric Conversion Element

A manufacturing method of a photoelectric conversion element according to the present embodiment includes a first charge transport layer forming step for forming a first charge transport layer containing a first charge transport material, a light absorption layer forming step for forming a light absorption layer on the first charge transport layer, and a second charge transport layer forming step for forming a second charge transport layer on the light absorption layer by coating a second charge transport layer coating solution containing a second charge transport material. One of the first charge transport material and the second charge transport material is an electron transport material, and the other is a hole transport material. The light absorption layer includes a perovskite compound having a needle-like crystal structure, and a binder resin.

In the manufacturing method of a photoelectric conversion element according to the present embodiment, the first charge transport material is preferably an electron transport material, and the second charge transport material is preferably a hole transport material. That is to say, in the manufacturing method of a photoelectric conversion element according to the present embodiment, an electron transport layer is formed in the first charge transport layer forming step, and a hole transport layer is formed in the second charge transport layer forming step.

The manufacturing method of the photoelectric conversion element 1 shown in FIG. 1 will be described as an example of the manufacturing method of a photoelectric conversion element according to the present embodiment. For example, the manufacturing method of the photoelectric conversion element 1 shown in FIG. 1 includes a laminated body preparation step for preparing a laminated body including a base 2 and a first conductive layer 3, an electron transport layer forming step for forming an electron transport layer 4 containing an electron transport material on the first conductive layer 3 of the laminated body, a light absorption layer forming step for forming a light absorption layer 6 on the electron transport layer 4, a hole transport layer forming step for forming a hole transport layer 7 by coating the light absorption layer 6 with a hole transport layer coating solution containing a hole transport material, and a second conductive layer forming step for forming a second conductive layer 8 on the hole transport layer 7. In the manufacturing method, the electron transport material is a first charge transport material, the hole transport material is a second charge transport material, and the hole transport layer coating solution is a second charge transport layer coating solution. That is to say, in the manufacturing method described above, the electron transport layer forming step is a first charge transport layer forming step, and the hole transport layer forming step is a second charge transport layer forming step.

### Laminated Body Preparation Step

In this step, a laminated body including a base 2 and a first conductive layer 3 is prepared. The laminated body is obtained, for example, by forming the first conductive layer 3 on the base 2. Examples of the method of forming the first conductive layer 3 on the base 2 include a vacuum deposition method, a sputtering method, and a plating method.

### Electron Transport Layer Forming Step

In this step, an electron transport layer 4 is formed on the first conductive layer 3 of the laminated body. Specifically, this step includes a dense titanium oxide layer forming step and a porous titanium oxide layer forming step.

### Dense Titanium Oxide Layer Forming Step

In this step, a dense titanium oxide layer 51 is formed on the first conductive layer 3 of the laminated body. Examples of the method of forming the dense titanium oxide layer 51 on the first conductive layer 3 include a method in which the first conductive layer 3 is coated with a dense titanium oxide layer coating solution containing a titanium chelate compound, and then sintered. Examples of the method of coating the first conductive layer 3 with the dense titanium oxide layer coating solution include a spin coating method, a screen printing method, a casting method, a dip coating method, a roll coating method, a slot die method, a spray pyrolysis method, and an aerosol deposition method. After the sintering, the dense titanium oxide layer 51 which is formed is immersed in an aqueous solution of titanium tetrachloride. This treatment enables the density of the dense titanium oxide layer 51 to be increased.

Examples of the solvent of the dense titanium oxide layer coating solution include alcohols (specifically 1-butanol). Examples of the titanium chelate compound included in the dense titanium oxide layer coating solution include compounds having an acetoacetate ester chelate group, and compounds having a β-diketone chelate group.

Examples of the compound having an acetoacetate ester chelate group are not particularly limited, and include diisopropoxytitanium bis(methylacetoacetate), diisopropoxytitanium bis(ethylacetoacetate), diisopropoxytitanium bis(propylacetoacetate), diisopropoxytitanium bis(butylacetoacetate), dibutoxytitanium bis(methylacetoacetate), dibutoxytitanium bis(ethylacetoacetate), triisopropoxytitanium(methylacetoacetate), triisopropoxytitanium(ethylacetoacetate), tributoxytitanium(methylacetoacetate), tributoxytitanium(ethylacetoacetate), isopropoxytitanium tri(methylacetoacetate), isopropoxytitanium tri(ethylacetoacetate), isobutoxytitanium tri(methylacetoacetate), and isobutoxytitanium tri(ethylacetoacetate).

Examples of the compound having a β-diketone chelate group are not particularly limited, and include diisopropoxytitanium bis(acetylacetonate), diisopropoxytitanium bis(2,4-heptanedionate), dibutoxytitanium bis(acetylacetonate), dibutoxytitanium bis(2,4-heptanedionate), triisopropoxy titanium(acetylacetonate), triisopropoxy titanium(2,4-heptanedionate), tributoxy titanium(acetylacetonate), tributoxy titanium(2,4-heptanedionate), isopropoxy titanium tri (acetylacetonate), isopropoxytitanium tri(2,4-heptanedionate), isobutoxytitanium tri(acetylacetonate), and isobutoxytitanium tri(2,4-heptanedionate).

The titanium chelate compound is preferably a compound having an acetoacetate ester chelate group, and is more preferably diisopropoxytitanium bis(methylacetoacetate). A commercially available product such as the “TYZOR (registered trademark) AA” series manufactured by DuPont may be used as the titanium chelate compound.

### Porous Titanium Oxide Layer Forming Step

In this step, a porous titanium oxide layer 52 is formed on the dense titanium oxide layer 51. Examples of the method of forming the porous titanium oxide layer 52 include a method in which the dense titanium oxide layer 51 is coated with a porous titanium oxide layer coating solution containing titanium oxide, and then sintered. The porous titanium oxide layer coating solution contains, for example, a solvent and an organic binder. If the porous titanium oxide layer coating solution contains an organic binder, the organic binder is removed by sintering. Examples of the method of coating the dense titanium oxide layer 51 with the porous titanium oxide layer coating solution include a spin coating method, a screen printing method, a casting method, a dip coating method, a roll coating method, a slot die method, a spray pyrolysis method, and an aerosol deposition method.

The pore diameter and porosity (void ratio) of the porous titanium oxide layer 52 are adjusted by, for example, the particle diameter of the titanium oxide particles included in the porous titanium oxide layer coating solution, and the type and content of the organic binder.

The titanium oxide included in the porous titanium oxide layer coating solution is not particularly limited, and examples include anatase-type titanium oxide. The porous titanium oxide layer coating solution may be prepared by, for example, dispersing titanium oxide particles (more specifically, “AEROXIDE (registered trademark) TiO₂ P25” manufactured by Nippon Aerosil Co., Ltd., and the like) in an alcohol (such as ethanol). The porous titanium oxide layer coating solution may be prepared by, for example, diluting a titanium oxide paste (more specifically, “PST-18NR” manufactured by JGC Catalysts and Chemicals Ltd.) in an alcohol (such as ethanol).

If the porous titanium oxide layer coating solution contains an organic binder, the organic binder is preferably ethyl cellulose or an acrylic resin. Acrylic resins have excellent low-temperature decomposability, and organic substances hardly remain inside the porous titanium oxide layer 52 even when sintering is performed at a low temperature. The acrylic resin preferably decomposes at a temperature of about 300° C. Examples of the acrylic resin include polymers of at least one type of (meth)acrylic monomer. Examples of the (meth)acrylic monomer include methyl(meth)acrylate, ethyl(meth)acrylate, propyl(meth)acrylate, n-butyl(meth)acrylate, tert-butyl(meth)acrylate, isobutyl(meth)acrylate, cyclohexyl(meth)acrylate, 2-ethylhexyl(meth)acrylate, isobornyl(meth)acrylate, n-stearyl(meth)acrylate, benzyl(meth)acrylate, and (meth)acrylic monomers having a polyoxyalkylene structure.

### Light Absorption Layer Forming Step

In this step, a light absorption layer 6 is formed on the electron transport layer 4 (specifically, on the porous titanium oxide layer 52). This step is preferably performed in air (under normal humidity) from the perspective of reducing manufacturing costs. Examples of the method of forming the light absorption layer 6 on the electron transport layer 4 include a method comprising a porous perovskite compound layer forming step for forming a porous layer containing a perovskite compound having a needle-like crystal structure (sometimes described as a porous perovskite compound layer below) on the electron transport layer 4, and a step for coating the porous perovskite compound layer with a binder resin solution containing binder resin and a solvent (binder resin solution coating step). According to this method, the light absorption layer 6 is formed as a result of the binder resin solution permeating into the porous perovskite compound layer.

### Porous Perovskite Compound Layer Forming Step

In this step, a porous layer containing a perovskite compound having a needle-like crystal structure is formed on the electron transport layer 4 (specifically, on the porous titanium oxide layer 52). When the perovskite compound is the perovskite compound (1), the porous perovskite compound layer is formed, for example, by the following one-step method or two-step method.

In the one-step method, a solution containing a compound represented by the general formula “AX” (referred to as compound (AX) below) and a compound represented by the general formula “BX₂” (referred to as compound (BX₂) below)) are mixed to obtain a mixed solution. The symbols A, B, and X in the general formula “AX” and the general formula “BX₂” each have the same definitions as the symbols A, B, and X in general formula (1). The porous titanium oxide layer 52 is coated with the mixed solution and dried to form a porous layer containing the perovskite compound (1) represented by the general formula “ABX₃”. Examples of the method of coating the porous titanium oxide layer 52 with the mixed solution include a dip coating method, a roll coating method, a spin coating method, and a slot die method.

In the two-step method, the porous titanium oxide layer 52 is coated with a solution containing the compound (BX₂) to form a coating film. The coating film is coated with a solution containing the compound (AX) to react the compound (BX₂) and the compound (AX) in the coating film. Then, the coating film is dried to form a porous layer containing the perovskite compound (1) represented by the general formula “ABX₃”. Examples of the method of coating the porous titanium oxide layer 52 with the solution containing the compound (BX₂) and method of coating the coating film with the solution containing the compound (AX) include a dip coating method, a roll coating method, a spin coating method, and a slot die method.

When performed in a normal environment, the perovskite compound (1) having a needle-like crystal structure is formed in both the one-step method and the two-step method due to the influence of moisture.

### Binder Resin Solution Coating Step

In this step, the porous perovskite compound layer is coated with a binder resin solution containing a binder resin and a solvent. The solvent is preferably a solvent that hardly affects the crystal structure of the perovskite compound. Specific examples of the solvent include toluene, chlorobenzene, ethyl acetate, and diethyl ether. Toluene and chlorobenzene are preferred.

Examples of the method of coating the porous perovskite compound layer with the binder resin solution include a dip coating method, a roll coating method, a spin coating method, and a slot die method. A dip coating method, a roll coating method, or a spin coating method are preferred.

The content ratio of the binder resin in the binder resin solution is preferably 0.1 mass % or more and 5.0 mass % or less, and more preferably 1.0 mass % or more and 2.0 mass % or less. By setting the content ratio of the binder resin to 0.1 mass % or more, a sufficient amount of the binder resin permeates into the porous perovskite compound layer. By setting the content ratio of the binder resin to 5.0 mass % or less, the viscosity of the binder resin solution is appropriately reduced, which enables the solution to more easily permeate into the porous perovskite compound layer.

In the light absorption layer forming step, in addition to the method described above, the electron transport layer 4 may, for example, be coated with a light absorption layer coating solution containing a perovskite compound and a binder resin.

### Hole Transport Layer Forming Step

In this step, the light absorption layer 6 is coated with a hole transport layer coating solution containing a hole transport material to form a hole transport layer 7. The hole transport layer coating solution contains, for example, a hole transport material and an organic solvent. The organic solvent of the hole transport layer coating solution is not particularly limited. For example, an alcohol solvent (specifically, isopropyl alcohol) or the like can be used. Furthermore, in order to more easily maintain the crystal structure of the perovskite compound in the light absorption layer 6, chlorobenzene or toluene may be used as the organic solvent of the hole transport layer coating solution. The content ratio of the hole transport material in the hole transport layer coating solution is, for example, 0.5 mass % or more and 5 mass % or less.

The hole transport layer coating solution preferably further contains a dispersant in addition to the hole transport material. The content ratio of the dispersant in the hole transport layer coating solution is, for example, 0.5 mass % or more and 5 mass % or less.

Examples of the coating method of the hole transport layer coating solution include a dip coating method, a spray coating method, a slide hopper coating method, and a spin coating method.

### Second Conductive Layer Forming Step

In this step, a second conductive layer 8 is formed on the hole transport layer 7. The method of forming the second conductive layer 8 on the hole transport layer 7 is not particularly limited. The same method as the method of forming the first conductive layer 3 (such as a vacuum deposition method, a sputtering method, or a plating method) is used.

### Other

The manufacturing method of the photoelectric conversion element 1 in FIG. 1 was described above as an example of the manufacturing method of a photoelectric conversion element according to the present embodiment. However, the manufacturing method of a photoelectric conversion element according to the present embodiment is not limited to the manufacturing method described above. For example, the following aspects can be changed.

The manufacturing method of a photoelectric conversion element according to the present embodiment may further include a surface layer forming step for forming a surface layer on the second conductive layer. Furthermore, the manufacturing method of a photoelectric conversion element according to the present embodiment does not have to include the laminated body preparation step and the second conductive layer forming step. In addition, in the electron transport layer forming step, the electron transport layer may be formed by a method other than the dense titanium oxide layer forming step and the porous titanium oxide layer forming step described above.

In the manufacturing method of a photoelectric conversion element according to the present embodiment, the light absorption layer is formed in a coating step performed in air. Therefore, the photoelectric conversion element is produced at low cost. Furthermore, the perovskite compound having a needle-like crystal structure is more stably produced than a perovskite compound having a plate-like crystal structure. Consequently, the manufacturing method of a photoelectric conversion element according to the present embodiment has an excellent yield. In addition, the photoelectric conversion element obtained by the manufacturing method of a photoelectric conversion element according to the present embodiment has excellent photoelectric conversion efficiency, and the light absorption layer has flexibility.

### EXAMPLES

Hereinafter, the present invention will be further described using examples. However, the present invention is in no way limited to the examples.

### Production of Photoelectric Conversion Element

The photoelectric conversion elements of Examples 1 to 6 and Comparative Examples 1 and 2 were produced according to the following methods.

### Example 1

### Laminated Body Preparation Step

A transparent glass plate (manufactured by Sigma-Aldrich Corp., film thickness: 2.2 mm) on which fluorine-doped tin oxide was deposited was cut into a size of 25 mm width and 25 mm length. As a result, a laminated body including a base (transparent glass plate) and a first conductive layer (deposited film of fluorine-doped tin oxide) was prepared. The laminated body was subjected to ultrasonic cleaning treatment in ethanol (1 hour) and UV cleaning treatment (30 minutes).

### Dense Titanium Oxide Layer Forming Step

A 1-butanol solution containing diisopropoxytitanium bis(acetylacetonate) as a titanium chelate compound at a concentration of 75 mass % (manufactured by Sigma-Aldrich Corp.) was diluted with 1-butanol. Consequently, a dense titanium oxide layer coating solution was prepared in which the concentration of the titanium chelate compound was 0.02 mol/L. The first conductive layer of the laminated body described above was coated with the dense titanium oxide layer coating solution by a spin coating method, followed by heating at 450° C. for 15 minutes. As a result, a dense titanium oxide layer having a thickness of 50 nm was formed on the first conductive layer.

### Porous Titanium Oxide Layer Forming Step

A porous titanium oxide layer coating solution was prepared by diluting 1 g of a titanium oxide paste containing titanium oxide and ethanol (“PST-18NR” manufactured by JGC Catalysts and Chemicals Ltd.) with 2.5 g of ethanol. The dense titanium oxide layer described above was coated with the porous titanium oxide layer coating liquid using a spin coating method, followed by sintering at 450° C. for 1 hour. As a result, a porous titanium oxide layer having a thickness of 300 nm was formed on the dense titanium oxide layer.

### Light Absorption Layer Forming Step

A light absorption layer was formed on the porous titanium oxide layer described above according to the following method. The formation of the light absorption layer was carried out in air.

### Porous Perovskite Compound Layer Forming Step

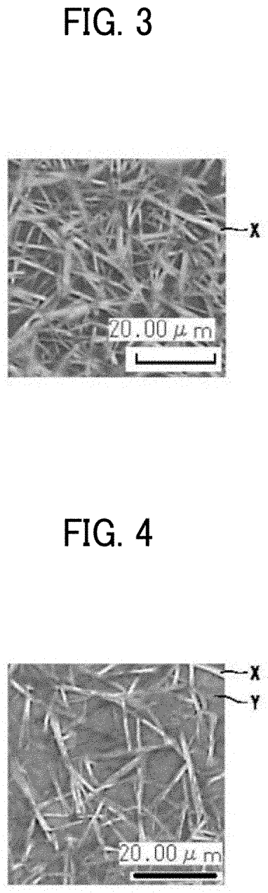

A mixture of 922 mg of PbI₂ (manufactured by Tokyo Chemical Industry Co., Ltd.) and 318 mg of CH₃NH₃I (manufactured by Tokyo Chemical Industry Co., Ltd.) was heated and dissolved in 1.076 mL of N,N-dimethylformamide (DMF) (mole ratio between PbI₂ and CH₃NH₃I=1:1). As a result, a mixed solution A having a solid content concentration of 55 mass % was prepared. The porous titanium oxide layer described above was coated with the mixed solution A using a spin coating method. When a few drops of toluene were dripped onto the liquid film immediately after coating, the liquid film changed from yellow to black. This enabled the formation of the perovskite compound (CH₃NH₃PbI₃) to be confirmed. Then, the liquid film was dried at 100° C. for 60 minutes. As a result, a porous perovskite compound layer having a thickness of 500 nm was formed on the porous titanium oxide layer. Observation of the surface of the porous perovskite compound layer with an optical microscope enabled confirmation of the formation of a porous region by a perovskite compound X having a needle-like crystal structure (FIG. 3).

### Binder Resin Solution Coating Step

To 5.68 mL of a toluene solvent was dissolved 0.1 g of a polyvinyl butyral resin (“S-LEC BL-S” manufactured by Sekisui Chemical Co., Ltd.) as a binder resin. The porous perovskite compound layer described above was coated with the obtained binder resin solution by using a spin coating method. Then, the coated binder resin solution was naturally dried. This resulted in the formation of the light absorption layer. Observation of the surface of the light absorption layer with an optical microscope enabled confirmation of the formation of porous regions by a perovskite compound X having a needle-like crystal structure, and the filling of the voids by a binder resin Y (FIG. 4). Using an optical microscope, the long axis length and the aspect ratio (long axis length/short axis length) were measured for an arbitrary 20 perovskite compounds, and the arithmetic average value was obtained. The long axis length of the perovskite compound was 20 μm, and the aspect ratio was 15.

### Hole Transport Layer Forming Step

To 12.21 mL of isopropyl alcohol was dispersed 0.2 g of multi-walled carbon nanotubes (MWCNT) (manufactured by Sigma-Aldrich Corp.) and 0.2 g of a dispersant. As a result, a hole transport layer coating solution was prepared. The light absorption layer described above was coated with the hole transport layer coating solution using a spin coating method. Then, the organic solvent (isopropyl alcohol) was removed by drying the coated hole transport layer coating solution at 100° C. for 30 minutes. As a result, a hole transport layer having a thickness of 500 nm was formed on the light absorption layer described above.

### Second Conductive Layer Forming Step

A gold vapor deposition film having a thickness of 150 nm, a width of 25 mm and a length of 25 mm was formed as an anode on the hole transport layer described above by a vacuum vapor deposition method. As a result, the photoelectric conversion element of Example 1, including a base, a first conductive layer, an electron transport layer (specifically, a dense titanium oxide layer and a porous titanium oxide layer), a light absorption layer, a hole transport layer, and a second conductive layer was obtained.

Other than modifying the aspects below, the photoelectric conversion elements of Examples 2 to 6 and Comparative Examples 1 and 2 were produced according to the same method as Example 1.

### Example 2

In the production of the photoelectric conversion element of Example 2, 0.1 g of a polyvinyl butyral resin (“S-LEC BM-S” manufactured by Sekisui Chemical Co., Ltd.) was used as the binder resin when preparing the binder resin solution.

### Example 3

In the production of the photoelectric conversion element of Example 3, 0.1 g of a polyvinyl butyral resin (“S-LEC BH-S” manufactured by Sekisui Chemical Co., Ltd.) was used as the binder resin when preparing the binder resin solution.

### Example 4

In the production of the photoelectric conversion element of Example 4, 0.1 g of an ethyl cellulose resin (manufactured by Kishida Chemical Co., Ltd.) was used as the binder resin when preparing the binder resin solution.

### Example 5

In the production of the photoelectric conversion element of Example 5, 0.917 g of chlorobenzene was used as the solvent when preparing the binder resin solution.

### Example 6

In the production of the photoelectric conversion element of Example 6, instead of coating a binder resin solution after forming the porous perovskite compound layer as in Example 1, the light absorption layer was formed by coating a light absorption layer coating solution as follows. The formation of the light absorption layer was carried out in air.

### Light Absorption Layer Forming Step

After preparing the mixed solution A having the composition described in Example 1, 10 mg of a polyvinyl butyral resin (“S-LEC BL-S” manufactured by Sekisui Chemical Co., Ltd.) was further added and dissolved in the mixed solution A. This resulted in the preparation of a light absorption layer coating solution.

The porous titanium oxide layer described above was coated with the light absorption layer coating solution described above using a spin coating method. When a few drops of toluene were dripped onto the liquid film immediately after coating, the liquid film changed from yellow to black. This enabled the formation of the perovskite compound (CH₃NH₃PbI₃) to be confirmed. In the production of the photoelectric conversion element of Example 6, the time between the dripping of the toluene to the start of the change in color of the liquid film from yellow to black was slightly longer than in Comparative Example 1.

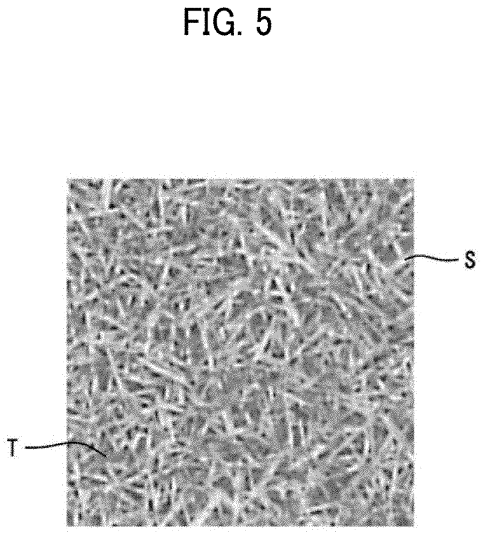

Then, the liquid film was dried at 100° C. for 60 minutes. As a result, a light absorption layer having a thickness of 500 nm was formed on the porous titanium oxide layer. Observation of the surface of the light absorption layer with an optical microscope enabled confirmation of the formation of porous regions by a perovskite compound S having a needle-like crystal structure, and the filling of the voids by a binder resin T (FIG. 5).

### Comparative Example 1

In the production of the photoelectric conversion element of Comparative Example 1, the binder resin solution coating step was not performed in the light absorption layer forming step. That is to say, In the production of the photoelectric conversion element of Comparative Example 1, the hole transport layer was formed on the porous perovskite compound layer after the porous perovskite compound layer forming step.

### Comparative Example 2

In the production of the photoelectric conversion element of Comparative Example 2, the binder resin solution coating step was not performed in the light absorption layer forming step. Furthermore, in the production of the photoelectric conversion element of Comparative Example 2, the light absorption layer forming step was performed under an inert atmosphere (nitrogen gas atmosphere) using a glove box. In the production of the photoelectric conversion element of Comparative Example 2, observation of the surface of the light absorption layer that was formed with an optical microscope enabled confirmation of the formation of a layer of a perovskite compound having a plate-like crystal structure.

The manufacturing methods of the photoelectric conversion elements of Examples 1 to 6 and Comparative Examples 1 and 2 are presented in Table 1 below. In Table 1 below, “PVB (BL-S)”, “PVB (BM-S)” and “PVB (BH-S)” are respectively a polyvinyl butyral resin (“S-LEC BL-S” manufactured by Sekisui Chemical Co., Ltd.), and the BM-S and BH-S resins of the same product line.

TABLE 1

| | Light Absorption Layer | | | | Manufacturing Conditions | | |
|---|---|---|---|---|---|---|---|
| | Perovskite Compound | | | | Binder Resin Solution | | |
| | Crystal | Long Axis | Aspect | Binder | Binder | | |
| | Structure | Length [μm] | Ratio | Resin | Resin | Solvent | Atmosphere |
| Example 1 | Needle-like | 20 | 15 | PVB(BL-S) | PVB(BL-S) | Toluene | Air |
| Example 2 | Needle-like | 15 | 12 | PVB(BM-S) | PVB(BM-S) | Toluene | Air |
| Example 3 | Needle-like | 12 | 10 | PVB(BH-S) | PVB(BH-S) | Toluene | Air |
| Example 4 | Needle-like | 8 | 11 | Cellulose resin | Cellulose resin | Toluene | Air |
| Example 5 | Needle-like | 15 | 12 | PVB(BL-S) | PVB(BL-S) | Chlorobenzene | Air |
| Example 6 | Needle-like | 8 | 8 | PVB(BL-S) | — | — | Air |
| Comparative | Needle-like | 15 | 15 | — | — | — | Air |
| Example 1 | | | | | | | |
| Comparative | Plate-like | — | — | — | — | — | nitrogen gas |
| Example 2 | | | | | | | |

### Evaluation

The short-circuit current, the open-circuit voltage, the fill factor, and the photoelectric conversion efficiency of each of the photoelectric conversion elements of Examples 1 to 6 and Comparative Examples 1 and 2 were measured using a solar simulator (manufactured by Wacom Electric Co., Ltd.). The photoelectric conversion element was connected to the solar simulator so that the second conductive layer on the surface layer side of the photoelectric conversion element served as the anode, and the first conductive layer on the base side served as the cathode. The photoelectric conversion element was irradiated with a 100 mW/cm² simulated sunlight obtained by passing the light from a xenon lamp through an air mass filter (“AM-1.5” manufactured by Nikon Corporation). The current-voltage characteristics of the photoelectric conversion element at the time of irradiation were measured, and a current-voltage curve was obtained. The short-circuit current (Jsc), the open-circuit voltage (Voc), the fill factor (FF), and the photoelectric conversion efficiency (η) were calculated from the current-voltage curve. Higher numerical values of the short-circuit current, the open-circuit voltage, the fill factor, and the photoelectric conversion efficiency indicate a better photoelectric conversion element. The results are shown in Table 2 below.

The following testing was performed with respect to the photoelectric conversion elements of Examples 1 to 6 and Comparative Examples 1 and 2 to evaluate the flexibility of the light absorption layer. A light absorption layer was formed on a 100 mm×100 mm aluminum sheet by the same method as the light absorption layer forming step used when preparing the photoelectric conversion elements of Examples 1 to 6 and Comparative Examples 1 and 2. The obtained laminated body was used as a sample representing the flexibility of the light absorption layer in the photoelectric conversion elements of Examples 1 to 6 and Comparative Examples 1 and 2. Each sample was rounded into a cylinder, and then returned to the original sheet shape after being held for five seconds. Then, the surface of the light absorption layer was visually observed. In those cases where cracks did not appear, it was determined that the “light absorption layer has flexibility”. In those cases where cracks did appear, it was determined that the “light absorption layer does not have flexibility”. The results are shown in Table 2 below.

TABLE 2

| | Short- | Open- | | | Flexibility |
|---|---|---|---|---|---|
| | circuit | circuit | Fill | Conversion | of Light |
| | Current | Voltage | Factor | Efficiency | Absorption |
| | [mA/cm2] | [V] | [%] | [%] | Layer |
| Example 1 | 22.5 | 0.77 | 0.44 | 7.6 | Yes |
| Example 2 | 23.5 | 0.78 | 0.41 | 7.5 | Yes |
| Example 3 | 24.2 | 0.75 | 0.39 | 7.1 | Yes |
| Example 4 | 21.9 | 0.69 | 0.34 | 5.1 | Yes |
| Example 5 | 25.3 | 0.82 | 0.40 | 8.3 | Yes |
| Example 6 | 19.3 | 0.85 | 0.38 | 6.2 | Yes |
| Comparative | 14.3 | 0.48 | 0.29 | 2.0 | Yes |
| Example 1 | | | | | |
| Comparative | 20.5 | 1.01 | 0.45 | 9.3 | No |
| Example 2 | | | | | |

The photoelectric conversion element according Examples 1 to 6 includes an electron transport layer, a hole transport layer, and a light absorption layer disposed between the electron transport layer and the hole transport layer. The light absorption layer includes a perovskite compound having a needle-like crystal structure, and a binder resin. As a result, as shown in Table 2, the short-circuit current, the open-circuit voltage, the fill factor, and the conversion efficiency of the photoelectric conversion elements of Examples 1 to 6 are better than those of the photoelectric conversion element of Comparative Example 1. Furthermore, the light absorption layer in the photoelectric conversion elements of Examples 1 to 6 has flexibility. In addition, it is determined that the photoelectric conversion elements of Examples 1 to 6 can be produced at low cost because the light absorption layer can be formed in air.

On the other hand, the photoelectric conversion element of Comparative Example 2 includes a light absorption layer in which the perovskite compound is densely packed. As a result, as shown in Table 2, the light absorption layer in the photoelectric conversion element of Comparative Example 2 does not have flexibility. Furthermore, the short-circuit current, the open-circuit voltage, the fill factor, and the photoelectric conversion efficiency of the photoelectric conversion elements of Comparative Example 1 are worse than those of the photoelectric conversion elements of Examples 1 to 6. This is determined to be because, in the photoelectric conversion element of Comparative Example 1, the hole transport material permeated into the light absorption layer when the hole transport layer was formed, thereby causing a short circuit in the hole transport layer and the electron transport layer. Furthermore, although the photoelectric conversion element of Comparative Example 2 exhibited a good short-circuit current, open-circuit voltage, fill factor, and photoelectric conversion efficiency, the light absorption layer is formed under an inert atmosphere. Therefore, the manufacturing costs are determined to be high.

### INDUSTRIAL APPLICABILITY

The photoelectric conversion element according to an embodiment of the present invention can be utilized in solar power systems such as mega solar systems, in solar batteries, and in power supplies for small portable devices.

### BRIEF DESCRIPTION OF THE REFERENCE SYMBOLS

1: Photoelectric conversion element, 2: Substrate, 3: First conductive layer, 4: Electron transport layer, 51: Dense titanium oxide layer, 52: Porous titanium oxide layer, 6: Light absorption layer, 7: Hole transport layer, 8: Second conductive layer

What is claimed is:

1. A photoelectric conversion element comprising:
an electron transport layer;
a hole transport layer; and
a light absorption layer disposed between the electron transport layer and the hole transport layer; wherein
the light absorption layer includes a perovskite compound having a needle-like crystal structure, and a binder resin.

2. The photoelectric conversion element according to claim 1, wherein
a long axis length of the perovskite compound is 5 μm or more and 50 μm or less, and
a ratio of a long axis length to a short axis length of the perovskite compound is 5 or more and 30 or less.

3. The photoelectric conversion element according to claim 1, wherein the binder resin includes a polyvinyl butyral resin or a cellulose resin.

4. The photoelectric conversion element according to claim 1, wherein the hole transport layer includes carbon nanotubes.

5. The photoelectric conversion element according to claim 1, wherein the electron transport layer includes titanium oxide.

6. The photoelectric conversion element according to claim 1, wherein the perovskite compound is represented by a following general formula (1):
ABX₃ (1)
where A represents an organic molecule, B represents a metal atom, and X represents a halogen atom.

7. A manufacturing method of a photoelectric conversion element, comprising:
forming a first charge transport layer containing a first charge transport material;
forming a light absorption layer on the first charge transport layer; and
forming a second charge transport layer on the light absorption layer by coating a second charge transport layer coating solution containing a second charge transport material; wherein
one of the first charge transport material and the second charge transport material includes an electron transport material, and another includes a hole transport material, and
the light absorption layer contains a perovskite compound having a needle-like crystal structure, and a binder resin.

8. The manufacturing method of a photoelectric conversion element according to claim 7, wherein the forming of the light absorption layer includes
forming a porous layer containing a perovskite compound having a needle-like crystal structure on the first charge transport layer, and
coating the porous layer with a binder resin solution containing a binder resin and a solvent.

9. The manufacturing method of a photoelectric conversion element according to claim 8, wherein the solvent includes toluene or chlorobenzene.

10. The manufacturing method of a photoelectric conversion element according to claim 8, wherein in the coating of the porous layer, the binder resin solution is coated by a dip coating method, a roll coating method, or a spin coating method.

11. The manufacturing method of a photoelectric conversion element according to claim 7, wherein the first charge transport material includes an electron transport material, and the second charge transport material includes a hole transport material.
